(19) United States
(12) Patent Application Publication
(10) Pub. No.: US 2026/0213391 A1
(43) Pub. Date: Jul. 23, 2026

(54) COMMUNICATION DEVICE

(71) Applicant: LITE-ON TECHNOLOGY CORPORATION, Taipie (TW)

(72) Inventors: Chia-Hung KU, Taipie (TW); Lin-Hui MA, Taipie (TW)

(21) Appl. No.: 19/422,520

(22) Filed: Dec. 17, 2025

Related U.S. Application Data
(60) Provisional application No. 63/746,308, filed on Jan. 17, 2025.

(30) Foreign Application Priority Data
Sep. 17, 2025 (CN) 202511327262.3

(51) Int. Cl. H01Q 1/02; H04B 1/036; H05K 7/20

(52) U.S. Cl. CPC H01Q 1/02; H04B 1/036; H05K 7/20

(57) ABSTRACT

A communication device is provided. The communication device comprises a radio frequency (RF) circuit board, a first antenna structure, a second antenna structure, and a heat dissipation structure. The first antenna structure and the second antenna structure are both electrically connected to the RF circuit board. The first antenna structure is separated from the second antenna structure. The heat dissipation structure is stacked with the RF circuit board and the first antenna structure along a longitudinal direction. The heat dissipation structure is disposed between the first antenna structure and the RF circuit board in the longitudinal direction.

This application claims the benefit of the U.S. provisional application Ser. No. 63/746,308, filed Jan. 17, 2025, and the CN application No. 202511327262.3, filed Sep. 17, 2025, the disclosures of which are incorporated by reference herein in its entirety.

### TECHNICAL FIELD

The present invention relates to a communication device, and more particularly, to a wireless communication device.

### BACKGROUND

With the increasing prevalence of wireless communication devices, practitioners in the related field are confronted with challenges arising from various sources of radio waves, which may radiate within the same spectrum and cause electromagnetic interference (EMI). In view of this, communication components for RF transmission and reception must be effectively isolated to limit electromagnetic disturbances to nearby elements and to prevent degradation of performance. Accordingly, reducing noise interference and improving heat dissipation are directions of continuous development for those skilled in the art.

### SUMMARY

In view of the prior art, the present disclosure provides a novel communication device. By configuring a first antenna structure and a second antenna structure in a separated arrangement, and by disposing a heat dissipation structure in the longitudinal direction between the first antenna structure and the RF circuit board, noise interference can be reduced and heat dissipation can be improved.

According to an aspect of the present invention, communication device is provided. The communication device comprises a radio frequency (RF) circuit board, a first antenna structure, a second antenna structure, and a heat dissipation structure. The first antenna structure and the second antenna structure are both electrically connected to the RF circuit board. The first antenna structure is separated from the second antenna structure. The heat dissipation structure is stacked with the RF circuit board and the first antenna structure along a longitudinal direction. The heat dissipation structure is disposed between the first antenna structure and the RF circuit board in the longitudinal direction.

The above summary is not intended to represent all embodiments or all aspects of the present invention. On the contrary, the above summary is merely provided as some examples illustrating novel aspects and features of the present invention. In order to make the embodiments and other objects, features, and advantages of the present invention more apparent and understandable, preferred embodiments are described in detail below with reference to the accompanying drawings. After the detailed description of various embodiments with reference to the drawings, those skilled in the art will be more able to understand other aspects of the present invention. A brief description of the drawings is provided as follows.

### BRIEF DESCRIPTION OF THE DRAWINGS

FIG. 1A illustrates an exploded view of a communication device according to an embodiment of the present disclosure along a longitudinal direction.

FIG. 1B illustrates a top view, taken of partial components of the communication device according to an embodiment of the present disclosure along the longitudinal direction.

FIG. 1C illustrates a schematic diagram of partial components of the communication device according to an embodiment of the present disclosure.

FIG. 1D illustrates a top view of partial components of the communication device according to an embodiment of the present disclosure along the longitudinal direction.

FIG. 1E illustrates a schematic diagram of partial components of the communication device according to an embodiment of the present disclosure.

FIG. 1F illustrates a bottom view, taken along the longitudinal direction, of a component of the communication device according to an embodiment of the present disclosure.

FIG. 1G illustrates a schematic diagram of partial components of the communication device according to an embodiment of the present disclosure.

FIG. 2A illustrates a schematic diagram of partial components of the communication device according to an embodiment of the present disclosure.

FIG. 2B illustrates a top view of the communication device according to an embodiment of the present disclosure along the longitudinal direction.

FIG. 3 illustrates a schematic diagram of the communication device according to an embodiment of the present disclosure.

### DETAILED DESCRIPTION

Detailed descriptions of the embodiments of the specification are disclosed below with reference to the accompanying drawings. Apart from the detailed descriptions provided, any embodiments in which the present invention can be used as well as any substitutions, modifications or equivalent changes of the said embodiments are within the scope of the disclosure, and the descriptions and definitions in the claims shall prevail. In the following detailed description, for purposes of explanation, numerous specific details are set forth in order to provide a thorough understanding of the disclosed embodiments. It will be apparent, however, that one or more embodiments may be practiced without these specific details. Additionally, well-known common steps or components are not described in detail to avoid unnecessarily limiting the present invention. The same or similar elements in the figures are represented by the same or similar symbols. It is important to note that the drawings are for illustration purposes only and do not represent the actual size or quantity of components, unless otherwise specified.

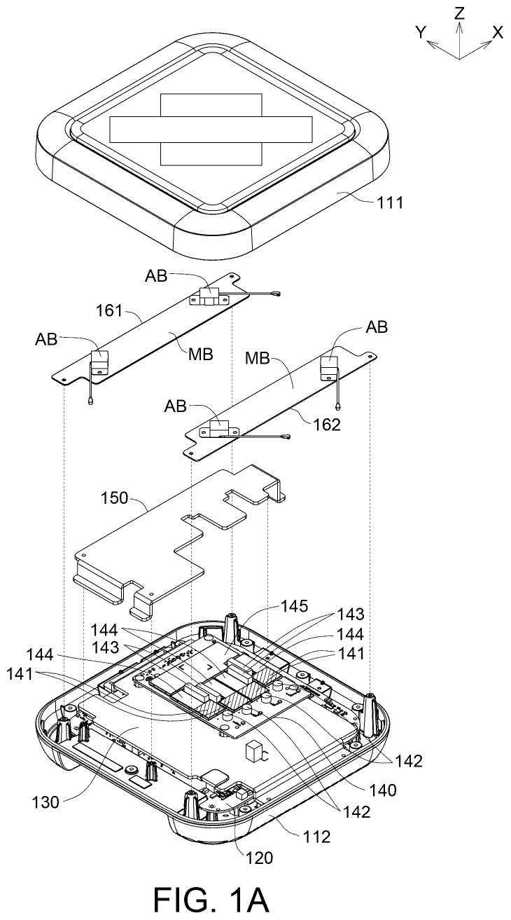

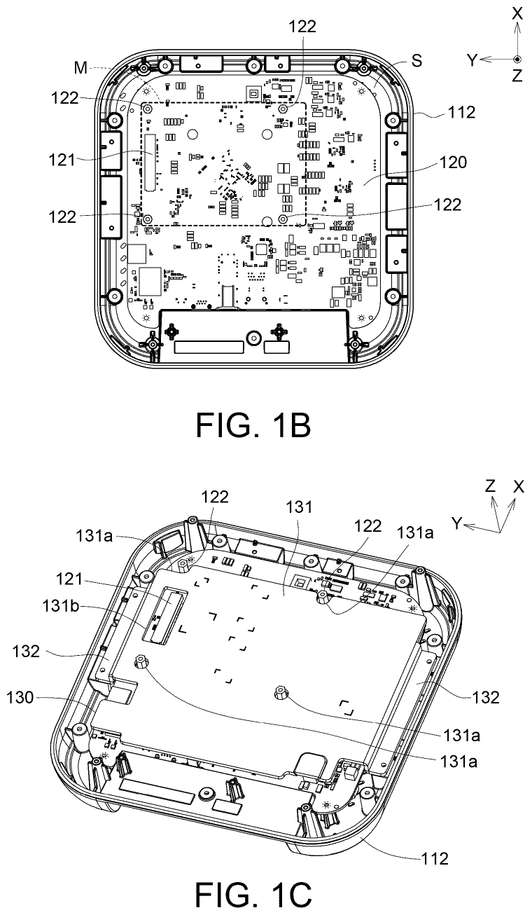

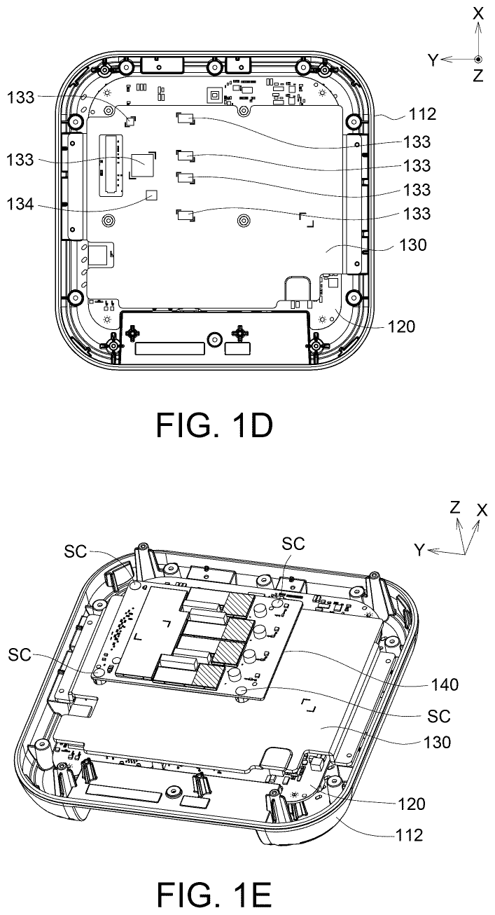

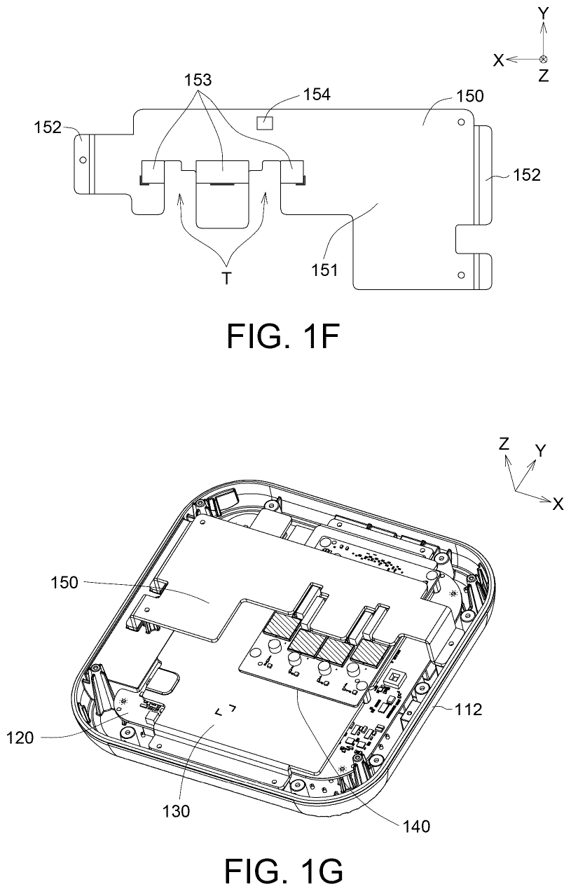

Please refer to FIGS. 1A to 1G. FIG. 1A is an exploded view of a communication device 100 according to an embodiment of the present disclosure along a longitudinal direction corresponding to a direction parallel to the Z-axis in FIG. 1A. FIG. 1B illustrates a top view of a lower cover 112 and a main circuit board 120 of the communication device 100 along the longitudinal direction. FIG. 1C illustrates a schematic diagram of the lower cover 112, the main circuit board 120, and a first heat dissipation structure 130. FIG. 1D illustrates a top view of the lower cover 112, the main circuit board 120, and the first heat dissipation structure 130 along the longitudinal direction. FIG. 1E illustrates a schematic diagram of the lower cover 112, the main circuit board 120, the first heat dissipation structure 130 and a radio frequency printed circuit board (RF PCB or RF circuit board) 140. FIG. 1F illustrates a bottom view of a second heat dissipation structure 150 along the longitudinal direction. FIG. 1G illustrates a schematic diagram of the lower cover 112, the main circuit board 120, the first heat dissipation structure 130, the RF circuit board 140, and the second heat dissipation structure 150.

The communication device 100 of the present disclosure may be a wireless communication device, such as a small cell adopting an open radio access network (O-RAN) architecture for fifth-generation (5G) mobile communication technology. As shown in FIG. 1A, the communication device 100 may comprise an upper cover 111, a lower cover 112, a main circuit board 120, a first heat dissipation structure 130, an RF circuit board 140, a second heat dissipation structure 150, a first antenna structure 161 and a second antenna structure 162.

As shown in FIG. 1B, the lower cover 112 has an accommodating space S. The main circuit board 120 is disposed within the accommodating space S by locking. The main circuit board 120 defines a rectangular mounting region M, in which a connection port 121 and a plurality of posts 122 are provided. In an embodiment, the connection port 121 may be disposed outside the mounting region M, and the plurality of posts 122 may be respectively disposed at the four corners of the mounting region M.

As shown in FIG. 1C, the first heat dissipation structure 130 includes a heat dissipation body 131 and a plurality of fastening elements 132. The plurality of fastening elements 132 are L-shaped and respectively connected to opposite side edges of the heat dissipation body 131. The first heat dissipation structure 130 covers an upper side of the main circuit board 120 such that the first heat dissipation structure 130 is locked and fastened to the lower cover 112 by the plurality of fastening elements 132. The heat dissipation body 131 has a plurality of first openings 131a corresponding to the plurality of posts 122 such that the plurality of posts 122 are exposed through the corresponding first openings 131a. The heat dissipation body 131 has a second opening 131b corresponding to the connection port 121 such that the connection port 121 is exposed through the second opening 131b.

In an embodiment, the first heat dissipation structure 130 is made of a metal material, such as aluminum. The heat dissipation body 131 and the plurality of fastening elements 132 may be integrally formed. As shown in FIG. 1D, in an embodiment, the first heat dissipation structure 130 is further provided with a plurality of thermal pads 133 and at least one first conductive pad 134. The plurality of thermal pads 133 and the at least one first conductive pad 134 are disposed in a region of the first heat dissipation structure 130 corresponding to (i.e., mapped from) the mounting region M.

As shown in FIGS. 1B and 1E, the RF circuit board 140 is disposed on the mounting region M of the first heat dissipation structure 130, and screws SC pass through the RF circuit board 140 to fasten to the plurality of posts 122, thereby fixing the RF circuit board 140 onto the plurality of posts 122. Furthermore, the RF circuit board 140 is electrically connected to the connection port 121 of the main circuit board 120 through the second opening 131b of the first heat dissipation structure 130. In an embodiment, the RF circuit board 140 is in contact with the plurality of thermal pads 133 such that a heat dissipation path is formed between the RF circuit board 140 and the first heat dissipation structure 130 through the plurality of thermal pads 133.

As shown in FIG. 1A, the RF circuit board 140 may include a receiving module 141, a circulator 142, a filter 143, a transmitting module 144 and an RF transceiver 145. The receiving module 141 is configured to receive signals and includes a low-noise amplifier (LNA) for performing primary amplification of weak signals, wherein four receiving modules 141 may be provided. The circulator 142 is configured to separate a transmitting path (TX path) and a receiving path (RX path) to prevent mutual interference between transmission and reception; four circulators 142 may be provided. The filter 143 may be a band-pass filter (BPF) configured to couple out transmission power signals for monitoring and protection to ensure stability and safety of the transmitting path, wherein four filters 143 may be provided. The transmitting module 144 is configured to transmit signals and includes a power amplifier (PA) to amplify the signal to a level suitable for antenna transmission, wherein four transmitting modules 144 may be provided.

In an embodiment, the plurality of thermal pads 133 are in contact with components of the RF circuit board 140, thereby dissipating heat through the first heat dissipation structure 130. In an embodiment, the first conductive pad 134 is a conductive foam, i.e., an EMI pad, which effectively provides electromagnetic shielding and grounding. Specifically, the first conductive pad 134 is typically bonded to a mechanical body or an electrical ground side by conductive adhesive tape, with conductive adhesive applied on the bottom surface of the first conductive pad 134. The first conductive pad 134 is attached to a mechanical body or a position intended to produce a shorting effect. When compressed, the polyurethane (PU) foam exerts a restoring force on the opposing contact point, thereby providing electrical conduction and localized shielding between structural components.

As shown in FIGS. 1F and 1G, the second heat dissipation structure 150 includes a heat dissipation body 151 and a plurality of fastening elements 152. One side edge of the heat dissipation body 151 is formed with a plurality of openings T. The plurality of fastening elements 152 are L-shaped and respectively connected to opposite side edges of the heat dissipation body 151. The second heat dissipation structure 150 covers the RF circuit board 140 such that the second heat dissipation structure 150 is fastened to the lower cover 112 by the plurality of fastening elements 152, and the filter 143 on the RF circuit board 140 is exposed through the plurality of openings T. In an embodiment, the second heat dissipation structure 150 is made of a metal material, such as aluminum. The heat dissipation body 151 and the plurality of fastening elements 152 may be integrally formed.

In the present embodiment, the second heat dissipation structure 150 is further provided with a plurality of thermal pads 153 and at least one second conductive pad 154. The plurality of thermal pads 153 and the at least one second conductive pad 154 are disposed in a region of the second heat dissipation structure 150 corresponding to (i.e., mapped from) the mounting region M. The plurality of thermal pads 153 are disposed adjacent to the plurality of openings T. In an embodiment, the plurality of thermal pads 153 are heat dissipation pads having electromagnetic compatibility (EMC) wave-absorbing functionality. The plurality of thermal pads 153 are in contact with components (such as power amplifiers) on the RF circuit board 140, and heat is dissipated through the second heat dissipation structure 150. Specifically, when the second heat dissipation structure 150 covers the RF circuit board 140, the plurality of thermal pads 153 are in contact with the RF circuit board 140, whereby another heat dissipation path is formed between the RF circuit board 140 and the second heat dissipation structure 150 through the plurality of thermal pads 153. In an embodiment, the second conductive pad 154 is a conductive foam, i.e., an EMI pad, which effectively provides electromagnetic shielding and grounding. Specifically, the second conductive pad 154 is typically bonded to a mechanical body or an electrical ground side by conductive adhesive tape, with conductive adhesive applied on the bottom surface of the second conductive pad 154. The second conductive pad 154 is attached to a mechanical body or a position intended to produce a shorting effect. When the PU foam is compressed, a restoring force is exerted on the opposite endpoint, thereby providing electrical conduction and localized shielding between structural components.

As shown in FIG. 1A, the first antenna structure 161 and the second antenna structure 162 may be both electrically connected to the RF circuit board 140. The first antenna structure 161 is separated from the second antenna structure 162, and the two are disposed at opposite sides of the lower cover 112. For example, each of the first antenna structure 161 and the second antenna structure 162 may include a metal antenna body MB and two antenna bases AB.

For example, the first antenna structure 161 and the second antenna structure 162 may be secured to the lower cover 112 by screw. Experimental validation has shown that by configuring the antenna architecture of the communication device 100 as separate and individually arranged antenna structures (such as the first antenna structure 161 and the second antenna structure 162), radiation interference sources can be avoided, thereby effectively reducing the error vector magnitude (EVM) and improving the quality of communication signals.

As shown in FIG. 1A, the upper cover 111 covers the first antenna structure 161 and the second antenna structure 162 and is locked and fastened to the lower cover 112.

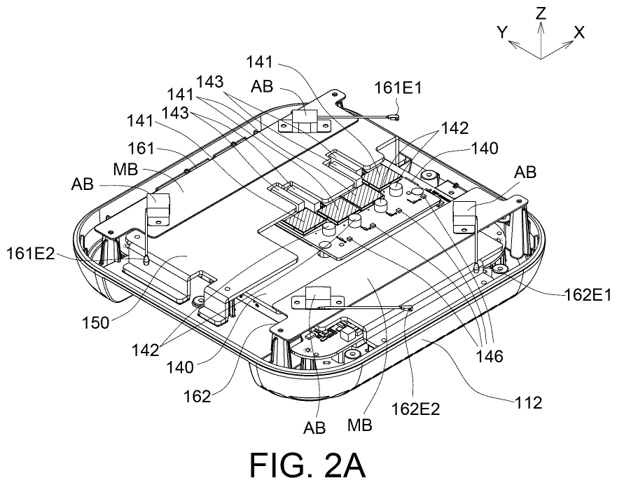

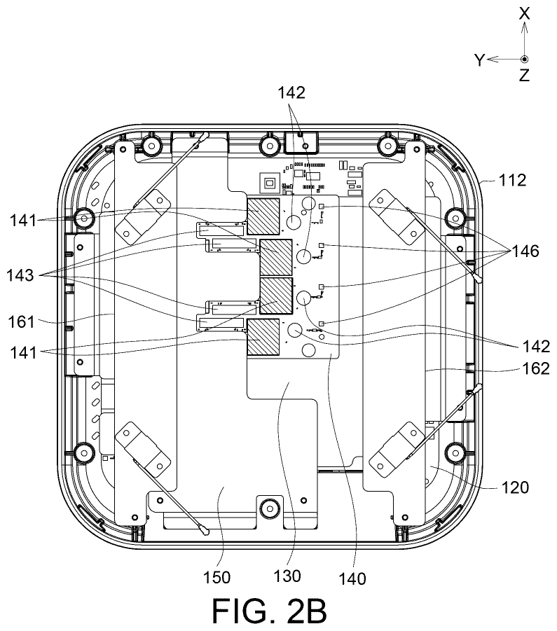

Please further refer to FIGS. 2A and 2B. FIG. 2A illustrates a schematic diagram of components of the communication device 100 other than the upper cover 111. FIG. 2B illustrates a top view of the components of the communication device 100 of FIG. 2A along the longitudinal direction (parallel to the Z-axis).

The second heat dissipation structure 150, the RF circuit board 140 and the first antenna structure 161 are stacked along the longitudinal direction parallel to the Z-axis. The second heat dissipation structure 150 is located between the first antenna structure 161 and the RF circuit board 140 along the longitudinal direction parallel to the Z-axis. The first heat dissipation structure 130 is stacked with the RF circuit board 140, the second heat dissipation structure 150 and the first antenna structure 161 along the longitudinal direction parallel to the Z-axis. The RF circuit board 140 is located between the second heat dissipation structure 150 and the first heat dissipation structure 130 along the longitudinal direction parallel to the Z-axis. The RF circuit board 140 may further include antenna connection points 146. The antenna connection points 146 provide signal connection with the first antenna structure 161 and the second antenna structure 162. In the present embodiment, four antenna connection points 146 may be provided. The first antenna structure 161 may include antenna end portions 161E1 and 161E2, which respectively extend from two antenna bases AB on the first antenna structure 161. The antenna end portions 161E1 and 161E2 may be electrically connected to two of the antenna connection points 146 on the RF circuit board 140 through RF cables (not shown). The second antenna structure 162 may include an antenna end portions 162E1 and 162E2, which respectively extend from two antenna bases AB on the second antenna structure 162. The antenna end portions 162E1 and 162E2 may be electrically connected to another two antenna connection points 146 on the RF circuit board 140 through RF cables (not shown).

As shown in FIG. 2B, due to the special shape design of the second heat dissipation structure 150, the four receiving modules 141 on the RF circuit board 140 do not overlap in projection with the second heat dissipation structure 150 along the longitudinal direction parallel to the Z-axis. The four circulators 142 on the RF circuit board 140 do not overlap in projection with the second heat dissipation structure 150 along the longitudinal direction parallel to the Z-axis. Likewise, the four filters 143 on the RF circuit board 140 do not overlap in projection with the second heat dissipation structure 150 along the longitudinal direction parallel to the Z-axis. That is, the second heat dissipation structure 150 does not cover the receiving modules 141, the circulators 142 and the filters 143 on the RF circuit board 140. In addition, please refer simultaneously to FIGS. 1A, 2A, and 2B. The transmitting modules 144 on the RF circuit board 140 overlap in projection with the second heat dissipation structure 150 along the longitudinal direction parallel to the Z-axis. The RF transceiver 145 on the RF circuit board 140 overlaps in projection with the second heat dissipation structure 150 along the longitudinal direction parallel to the Z-axis. That is, the second heat dissipation structure 150 covers the transmitting modules 144 and the RF transceiver 145 on the RF circuit board 140. Above the second heat dissipation structure 150, the first antenna structure 161 overlaps in projection with the second heat dissipation structure 150 along the longitudinal direction parallel to the Z-axis, whereas the second antenna structure 162 does not overlap in projection with the second heat dissipation structure 150 along the longitudinal direction parallel to the Z-axis. Furthermore, in the present embodiment, the first antenna structure 161 overlaps in projection with the RF circuit board 140 along the longitudinal direction parallel to the Z-axis (e.g., overlapping in projection with the RF transceiver 145), whereas the second antenna structure 162 does not overlap in projection with the RF circuit board 140 along the longitudinal direction parallel to the Z-axis.

Based on actual test, the error vector magnitude (EVM) of the communication device 100 using the design adopting the first antenna structure 161 and the second antenna structure 162 and was measured to be 2.4%. Regarding the scattering parameters (S-parameters), the results were obtained as shown in Table 1. Moreover, with the design adopting the second heat dissipation structure 150, the error vector magnitude (EVM) of the communication device 100 was measured to be 3.3%, and the high-temperature test results were obtained as shown in Table 2. Accordingly, through the special shape design of the first antenna structure 161, the second antenna structure 162, and the second heat dissipation structure 150, radiation interference sources can be avoided, effectively reducing the error vector magnitude, thereby enhancing the quality of communication signals.

TABLE 1

| | Antenna structure of the |
|---|---|
| Antenna | present disclosure (dB) |
| ANT1 Return Loss (dB) (3300 MHz) | −17.8 |
| ANT2 Return Loss (dB) (3300 MHz) | −19.7 |
| ANT1 Return Loss (dB) (3800 MHz) | −16.2 |
| ANT3 Return Loss (dB) (3800 MHz) | −18.2 |
| ANT4 Return Loss (dB) (3800 MHz) | −20.2 |
| ANT2 Efficiency (%) (3300 MHz) | 71 |
| ANT1-ANT4 Isolation (dB) (3300 MHz) | −26 |
| ANT1-ANT4 Isolation (dB) (3800 MHz) | −33 |
| ANT2-ANT3 Isolation (3300 MHz) | −37.4 |
| ANT2-ANT3 Isolation (3800 MHz) | −29 |
| ANT2-ANT4 Isolation (3800 MHz) | −35.7 |

TABLE 2

| | Specification/ | Heat dissipation structure of |
|---|---|---|
| Component number | Standard (° C.) | the present disclosure (° C.) |
| PA1 | 115 | 84.3 |
| PA2 | 115 | 92.7 |
| PA3 | 115 | 90.6 |
| PA4 | 115 | 86.8 |
| LDO1 | 114.73 | 82.3 |
| LDO2 | 114.73 | 84 |
| LDO3 | 114.73 | 84.6 |
| LDO4 | 114.73 | 84.4 |
| 1GPHY | 122 | 74.5 |
| POWER IC 1 | 123.4 | 69.3 |
| POWER IC 2 | 122.1 | 68.9 |
| POWER_MOS | 145.4 | 87.1 |
| POWER transformer | 125 | 82.2 |
| POWER_IC_PM8805TR | Tb = 130.5 | 82.8 |
| Si5518 | 105 | 73.7 |
| ADP5054 | 116.92 | 85.2 |

As shown in FIG. 2B, in a top-view (i.e., on the X-Y plane), in projection the Z-axis, the four receiving modules 141, the four circulators 142, the filter 143 and the four antenna connection points 146 are all located between the first antenna structure 161 and the second antenna structure 162. That is, the first antenna structure 161 and the second antenna structure 162 do not cover the receiving modules 141, the circulators 142, the filter 143, or the antenna connection points 146 on the RF circuit board 140.

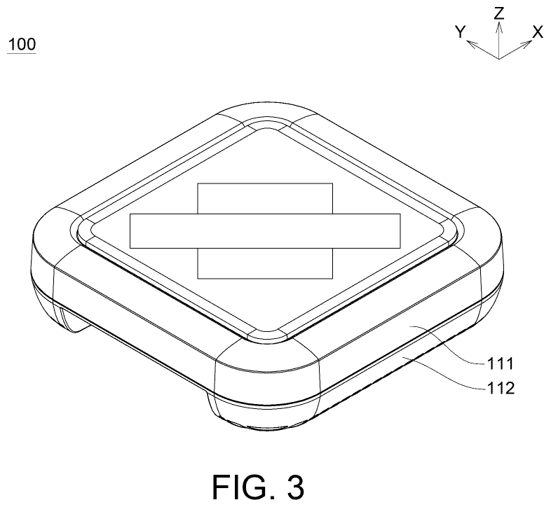

Please further refer to FIG. 3. FIG. 3 illustrates a schematic diagram of the communication device 100.

After the RF circuit board 140, the first antenna structure 161, the second antenna structure 162, the second heat dissipation structure 150 and the first heat dissipation structure 130 are assembled onto the lower cover 112, the upper cover 111 and the lower cover 112 may be combined along the longitudinal direction parallel to the Z-axis. That is, the upper cover 111 and the lower cover 112 may be assembled along the longitudinal direction parallel to the Z-axis to form a device housing of the communication device 100, such that the RF circuit board 140, the first antenna structure 161, the second antenna structure 162 and the second heat dissipation structure 150 are accommodated within the device housing. Thus, product assembly of the communication device 100 can be completed. The upper cover 111 and the lower cover 112 may be integrally formed components made of metal.

In summary, a novel communication device is provided in the present disclosure. By configuring the antenna architecture of the communication device into a plurality of separate and isolated antenna structures and further adopting special shape designs of built-in heat dissipation structures, noise interference can be effectively reduced and heat dissipation improved, thereby enhancing the quality of communication signals.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A communication device, comprising:
a radio-frequency (RF) circuit board;
a first antenna structure and a second antenna structure, both electrically connected to the RF circuit board, the first antenna structure being separated from the second antenna structure; and
a heat dissipation structure stacked with the RF circuit board and the first antenna structure along a longitudinal direction, the heat dissipation structure being located between the first antenna structure and the RF circuit board in the longitudinal direction.

2. The communication device of claim 1, wherein the RF circuit board includes a receiving module, a circulator and a filter, the receiving module does not overlap in projection with the heat dissipation structure in the longitudinal direction, the circulator does not overlap in projection with the heat dissipation structure in the longitudinal direction, and the filter does not overlap in projection with the heat dissipation structure in the longitudinal direction.

3. The communication device of claim 1, wherein the RF circuit board includes a transmitting module and an RF transceiver, the transmitting module overlaps in projection with the heat dissipation structure in the longitudinal direction, and the RF transceiver overlaps in projection with the heat dissipation structure in the longitudinal direction.

4. The communication device of claim 1, wherein the second antenna structure does not overlap in projection with the heat dissipation structure in the longitudinal direction, and the second antenna structure does not overlap in projection with the RF circuit board in the longitudinal direction.

5. The communication device of claim 1, wherein each of the first antenna structure and the second antenna structure comprises a metal antenna body and two antenna bases.

6. The communication device of claim 1, wherein the heat dissipation structure includes a heat-dissipation body and a plurality of fastening elements, the plurality of fastening elements are respectively connected to two opposite side edges of the heat-dissipation body.

7. The communication device of claim 1, wherein a plurality of thermal pads are disposed on the heat dissipation structure, and when the heat dissipation structure covers an upper side of the RF circuit board, the plurality of thermal pads are in contact with the RF circuit board, thereby enabling the RF circuit board to form a heat-dissipation path with the heat dissipation structure through the plurality of thermal pads.

8. The communication device of claim 1, further comprising a main circuit board disposed within an accommodating space of the communication device, the main circuit board defines a mounting region, a connection port and a plurality of posts are disposed in the mounting region.

9. The communication device of claim 8, further comprising an another heat dissipation structure disposed between the main circuit board and the RF circuit board, a plurality of thermal pads are disposed on the another heat dissipation structure, the RF circuit board is in contact with the plurality of thermal pads to form a heat-dissipation path with the another heat dissipation structure through the plurality of thermal pads.

10. The communication device of claim 1, further comprising an upper cover body and a lower cover body, the upper cover body and the lower cover body are assembled along the longitudinal direction to form a device housing, such that the RF circuit board, the first antenna structure, the second antenna structure and the heat dissipation structure are accommodated within the device housing.
